(19) United States
(12) Patent Application Publication
(10) Pub. No.: US 2015/0212126 A1
(43) Pub. Date: Jul. 30, 2015

(54) SYSTEM AND METHOD FOR UNIFIED POWER QUALITY MONITORING AND DATA COLLECTION IN A POWER SYSTEM HAVING HETEROGENEOUS DEVICES FOR MONITORING POWER QUALITY

(71) Applicant: ABB Technology AG, Zurich (CH)

(72) Inventor: Jeffrey Harding, Holly Springs, NC (US)

(73) Assignee: ABB Technology AG, Zurich (CH)

(21) Appl. No.: 14/604,006

(22) Filed: Jan. 23, 2015

Related U.S. Application Data
(60) Provisional application No. 61/931,631, filed on Jan. 26, 2014.

(51) Int. Cl. G01R 21/133; G06F 17/30

(52) U.S. Cl. CPC G01R 21/133; G06F 17/30876

(57) ABSTRACT

A power quality monitoring system and method standardizes power quality data obtained from heterogeneous devices such as power quality meters and other devices from various manufacturers. The power quality data is provided in a device independent and standardized format for use by web applications and other systems that manage and present the power quality data.

### FIELD OF INVENTION

The present application is directed to a system and method for unified monitoring, collecting, and standardizing of power quality data to support facility operations.

### BACKGROUND

Power meters often include advanced power quality data such as transient and harmonic data that is not readily available using traditional industrial data acquisition methods. The power meters monitor the power quality and upon detection of a disturbance, perform a high speed collection and storage of waveforms at the time of the disturbance.

Most power meters are delivered with software that collects power quality data from the specific brand of meter only. A facility having a collection of power quality meters from different manufacturers require multiple software systems to manage the power quality data from the collection of meters. Therefore, there is room for improvement in capturing, storing and utilizing data from heterogeneous power quality meters for the efficient management of power quality data in a facility such as a data center.

### SUMMARY

An object of the present disclosure is to provide a solution for standardizing power quality data obtained from heterogeneous power quality meters and provide the data in a standard format for use by web applications and other systems that manage and present the power quality data.

Another object of the present disclosure is to provide notification and alarming capabilities through usage, analysis and presentation to a user of the unified power quality data.

### BRIEF DESCRIPTION OF THE DRAWINGS

In the accompanying drawings, structural embodiments are illustrated that, together with the detailed description provided below, describe exemplary embodiments of a power quality monitoring system. One of ordinary skill in the art will appreciate that a component may be designed as multiple components or that multiple components may be designed as a single component.

Further, in the accompanying drawings and description that follow, like parts are indicated throughout the drawings and written description with the same reference numerals, respectively. The figures are not drawn to scale and the proportions of certain parts have been exaggerated for convenience of illustration.

FIG. 1 is an exemplary embodiment of a system for standardizing power quality data obtained from heterogeneous devices to provide the data in a common format to web browsers, web applications and other systems;

FIG. 2 shows components of a power quality server in communication with web and other applications;

FIG. 2a is a schematic of a federation service that unifies data from a plurality of power quality servers in an enterprise;

FIG. 2b is a schematic of a real-time database of the power quality monitoring system;

FIG. 2c is a schematic of a device disturbance property having disturbance(s) and parameter(s);

FIG. 3 shows abstraction performed at the device type level to provide device independent data;

FIG. 4 is an exemplary overview of a software application for monitoring power quality having graphical user interface (GUI) display of the plurality of devices being monitored in the power quality monitoring system;

FIG. 5 is an exemplary GUI display of one of the plurality of devices, specifically depicting energy consumption, peak power, current and voltage phasor analysis, and voltage and current of the system being measured;

FIG. 6 is an exemplary GUI display of the application of FIG. 4, showing the real, apparent and reactive power values of the system being measured by the device;

FIG. 7 shows the real, apparent and reactive energy values of the system being measured;

FIG. 8 shows current phasors, voltage phasors, line-to-line and line-to-neutral voltage values, and current values of the system being monitored;

FIG. 9 shows the voltage and current even and odd harmonic distortions for the system being monitored along with a time series chart for the selected distortion type;

FIG. 10 shows a waveform plot of a time window, the waveform plot capturing a disturbance in the waveform;

FIG. 11 shows a device management configuration tool; and

FIG. 12 shows a device discovery process in progress.

### DETAILED DESCRIPTION

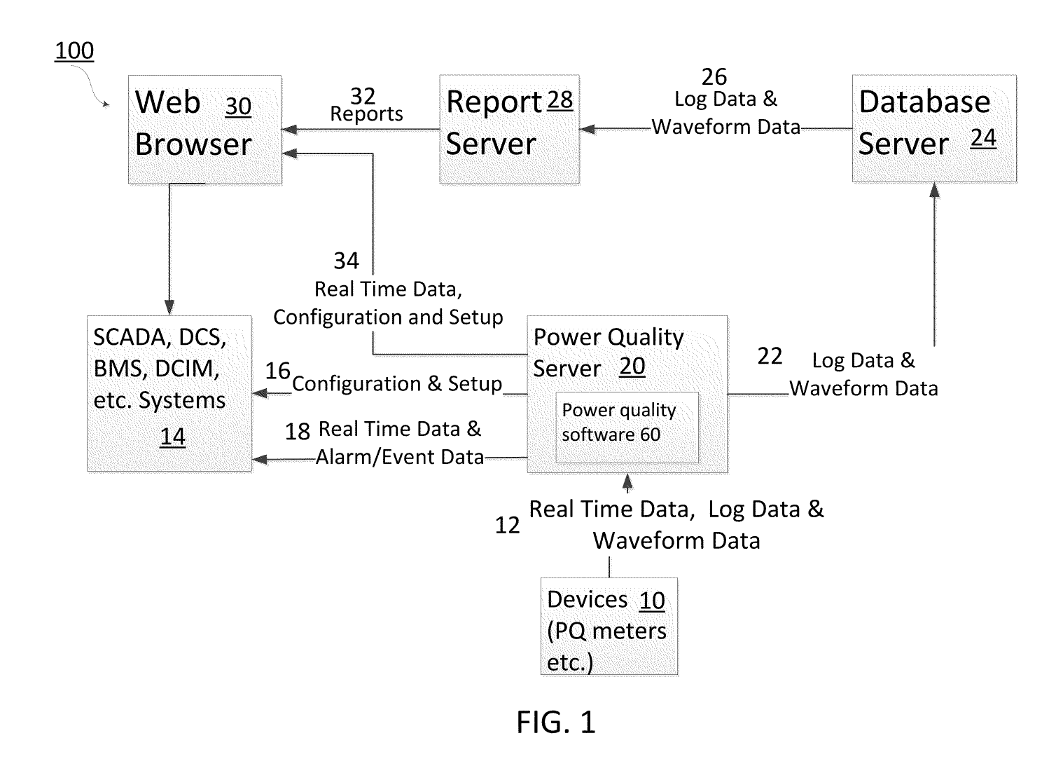

With reference to FIG. 1, a system 100 for monitoring, collecting, and standardizing power quality data (hereinafter “power quality system”) for transmission to a power quality server 20 from a plurality of devices 10 is depicted. The devices 10 are power quality meters or other electrical devices for monitoring and recording the property values of electricity in an electrical system. For example, the plurality of devices 10 may be uninterruptible power supplies (UPS) or branch circuit monitoring (BCM) devices that track actual usage of each power circuit using current transformers to measure the electrical current of each power circuit within a power distribution unit (PDU). It should be understood that many electrical devices 10 are contemplated, and the aforementioned are provided by way of non-limiting example. The electrical system may be in a data center, industrial facility or any other location that utilizes power quality meters to monitor operations of the power distribution system.

The power quality server 20 communicates to a plurality of heterogeneous devices 10 collecting real time, log and waveform data 12 for transmission to a database server 24 for storage in a common format. It should be understood that devices 10 such as power quality meters provide waveform data whereas other devices provide other types of data. The power quality server 20 supports one or more open and/or proprietary communication protocols to transmit real time, alarm and event data integration with supervisory control and data acquisition systems (SCADA), distributed control systems (DCS), building management systems (BMS), data center infrastructure management (DCIM) systems or any other systems that interface with the power quality server 20.

The devices 10 may be disparate devices 10 procured from different vendors, thus having disparate communication protocols 54. Examples of communication protocols 54 supported by the power quality system 100 are Modbus-TCP and Ethernet/IP, by way of non-limiting example. The power quality system 100 communicates to the plurality of devices 10 through software 60 that utilizes the open standard protocols as well as proprietary protocols.

Power quality software 60 is installed in the power quality server 20 or plurality of power quality servers and is a computer program product having computer-readable program instructions that when executed by a processor, carry out the steps of collecting, converting and unifying the data from disparate devices 10 installed at measurement points in an electrical system to provide a common output data format for storing, reporting and analysis of the power quality characteristics of the power system being monitored (such as a data center).

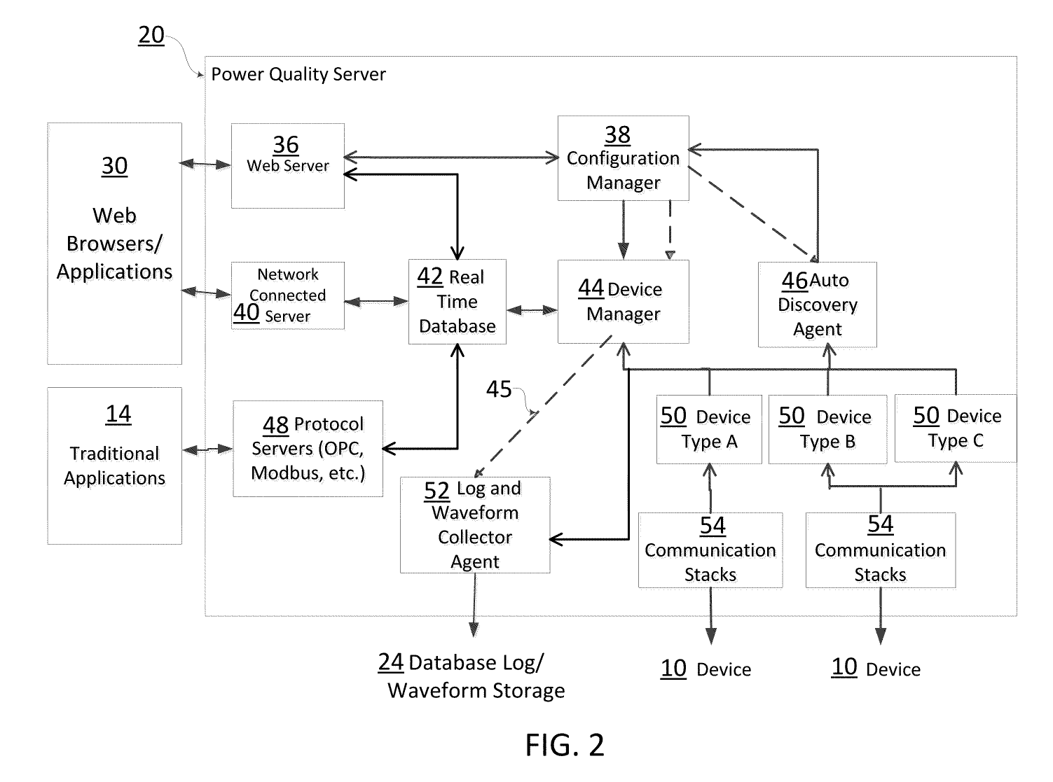

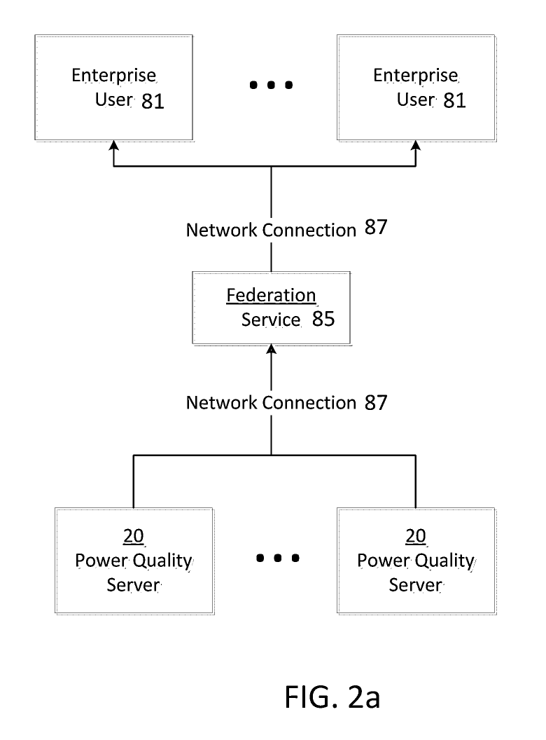

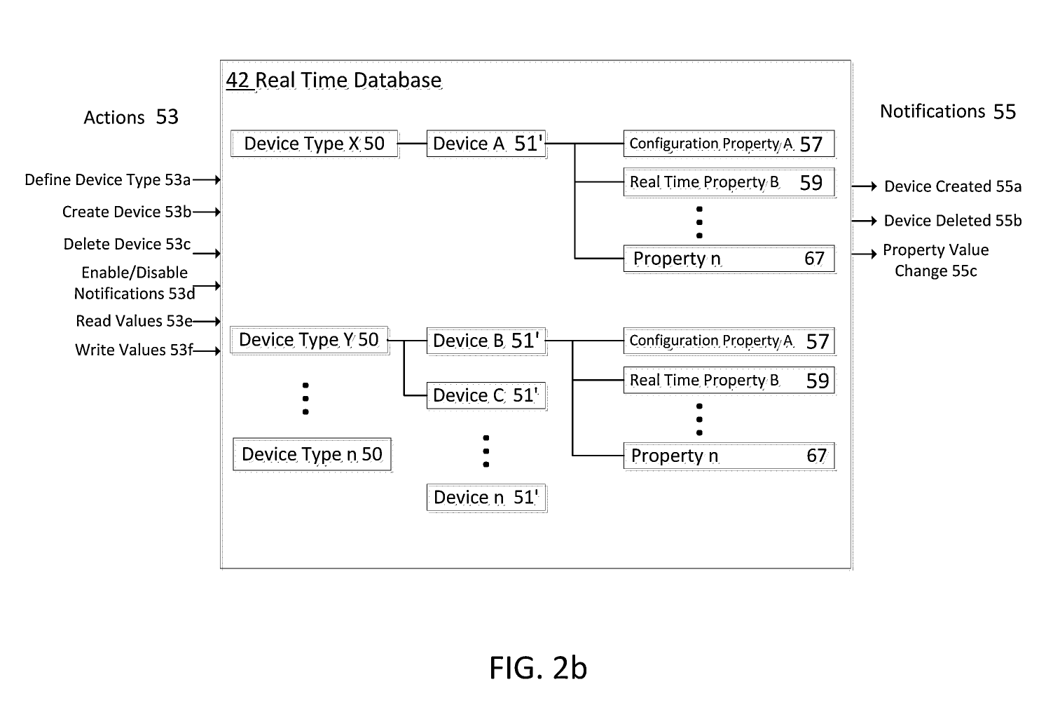

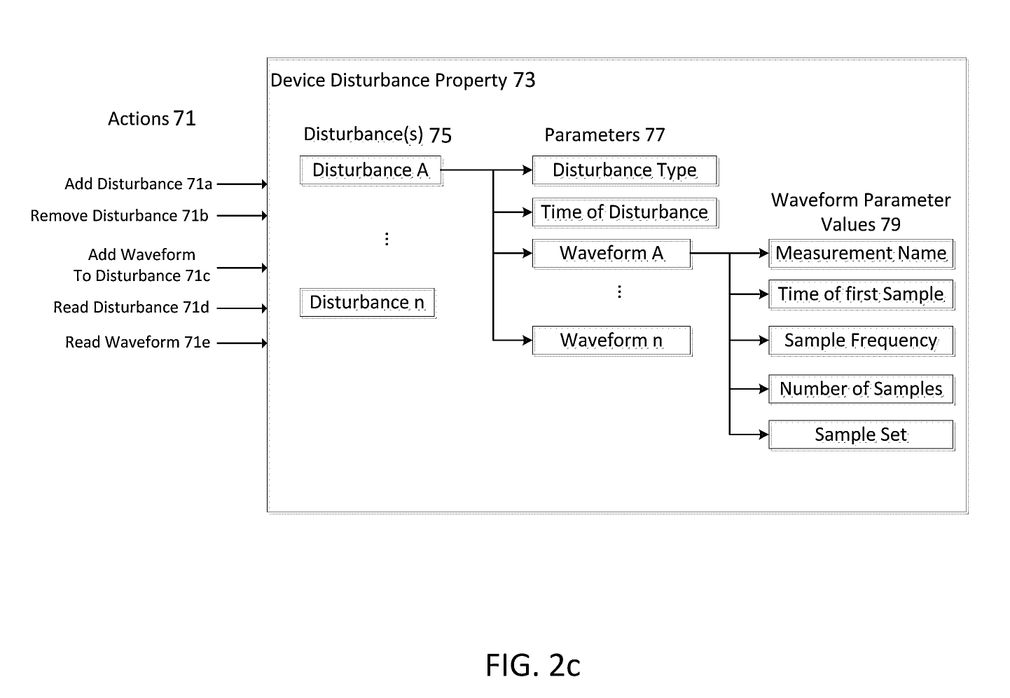

With reference now to FIG. 2a, the power quality software 60 can communicate with other software without requiring human interaction by using a network connection 87. In one embodiment, the network connection 87 is a service based on the WebSocket protocol. The power quality server 20 provides web pages and the web pages in turn use the network connection 87 to retrieve the data from the power quality server 20 and populate web pages accessible by the enterprise user 81. In one embodiment, the JavaScript programming language is used to create the network connection 87 to a network connected server 40 and a browser is not required. The power quality software 60 supports machine-to-machine interaction in this manner in that the power quality server 20 can communicate directly with other applications.

Other applications such as web-based and traditional applications 30, 14 are able to request and retrieve data from the plurality of power quality servers 20 without human interaction and, thus, network connected server 40 supports machine-to-machine interaction. The network connected server 40 is connected to the enterprise network and external applications 14, 30. In one embodiment, the network connected server 40 supports the WebSocket protocol. Further, a representation 51′ of each of the devices 10 that are visible to the plurality of power quality servers 20 are made part of an internet-of-things (IoT) and accessible to the enterprise users 81 and/or other applications 14, 30.

With continued reference to FIG. 2a, the plurality of power quality servers 20 across an enterprise are unified by federation service 85. For example, different locations within an enterprise may utilize different power quality servers 20. Each power quality server 20 has data from the various devices associated with a location. The data from the various locations is aggregated so that all devices across an enterprise are accessible to an enterprise user by the federation service 85 which acts as a security layer and a unification layer.

As the security layer, the federation service 85 may provide a single sign-on or another type of authentication for enterprise users to access the enterprise device data via the internet or enterprise intranet. In addition, the federation service 85 unifies the device 10 data across the enterprise so that the data from all devices 10 can be accessed from a single source. The federation service 85 uses a network connection 87 to retrieve data from the plurality of power quality servers 20 and for presentation to the enterprise user 81.

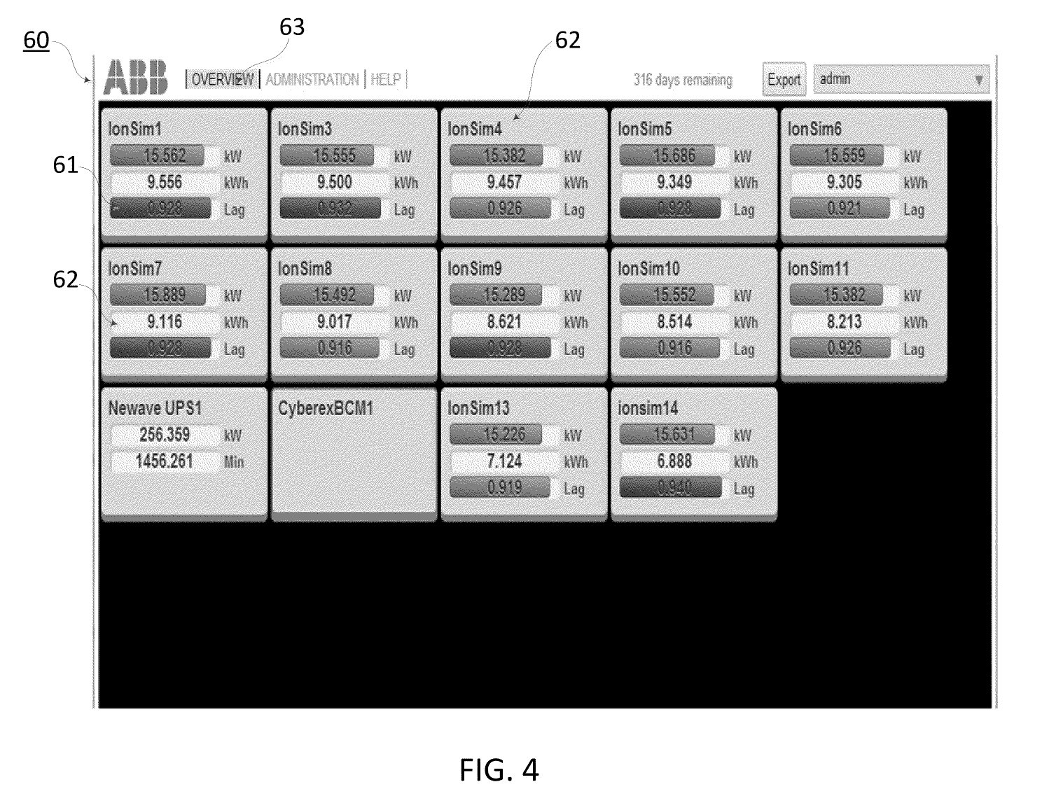

Power quality disturbance events generated by the devices 10 are detected by the power quality server 20. Alarms and events 18 are generated in real-time in response to a disturbance 75 and the resulting log and/or waveform data is uploaded from the devices 10 to the power quality server 20. The power quality server 20 interfaces with a database server 24 to store the collected log and waveform data. The log and waveform data includes but is not limited to voltage waveforms, current waveforms, phasors and all other power quality data displayed and described below in regard to an exemplary DCIM computer application 60 depicted in FIGS. 4-12.

The alarms and events 18 generated in response to disturbances 75 are communicated to other applications which notify the user of those applications 14, 30 of a problem in the power system being monitored.

Standalone web browsers 30 or systems with integrated web browser capability can access the power quality server 20 configuration and setup using a web-based user interface and/or web services. Standalone web browsers 30 or systems with integrated web browser capability access the stored log and waveform data via a report server 28 which formulates a web-based user interface using data from the database server 24.

With reference now to FIG. 2, the power quality server 20 components such as a web server 36, configuration manager 38, network connected server 40, real-time database 42, device manager 44, auto discovery agent 46, protocol servers 48, device types 50, waveform collection agent 52, and communication stacks 54 are shown. The configuration manger 38 manages the overall configuration of the power quality server 20 which includes general options and the specific configuration of each device 10. A web interface is exposed allow a user to view and modify the power quality server 20 configuration.

The device manager 44 manages the overall device 10 monitoring and schedules collection of status and real-time data. The device manager 44 periodically queries 45 the devices 10 to determine if new disturbances 75 have occurred. The device manager 44 collects real-time data from the devices 10 and maintains that data in a real time in-memory database 42 consisting of a set of configuration, measured and calculated properties. In one embodiment, the device manager 44 and the configuration manager 38 are a single component of system 100 and/or application 60, having the functionality of each merged into one component. The waveform collection agent 52 requests the device 10 to upload the waveform or other characteristic data. Once the waveform or other characteristic data is uploaded and normalized by the device type 50, the data is uploaded to the waveform log/storage database 24 server. The waveform and/or characteristic data is then accessible to the device manager 44 which retrieves the data from the waveform log/storage database 24 and transmits the real-time data to the real-time database 42. Once the waveform is stored in the real-time database 42, the waveform is available to the web browsers 30, DCIM applications 60, and other traditional applications 14 such as SCADA, DCS, BMS, or any other systems that interface with the power quality server 20.

The collector agent 52 performs the uploading of log and waveform data. The collector agent 52 uses the available device types 50 to first formulate device-specific requests by translating the normalized event data into device specific parameters which identify the log or waveform associated with the device(s) being polled by the collector agent 52. The collector agent 52 then delivers the request to the particular device(s). When a device-specific response is received from a device, the waveform or log data is translated by the device type into a normalized form. For example, the data format is converted from a real value to the string presentation of that value.

The normalized data is delivered to the storage database in a general format to ensure that device specific knowledge is not required outside the power quality server.

Communication stacks 54 enable the low-level communications to the devices 10. The communication stacks 54 support the retrieval of the real-time data as well as log and waveform data from the devices 10. The communication stacks 54 in conjunction with device type 50 translate the device 10 properties that are specific to the power quality meter manufacturer (or other type of electrical equipment having properties specific to a manufacturer) into device independent data.

For example, properties specific to a particular device 10 such as a power quality meter may be encoded with two time stamps such as trigger time and first sample time or the power quality meter may provide an offset from trigger time to first sample such as number of microseconds from trigger time to first sample time. Alternatively, the number of samples over a particular time frame is provided and the sampling times and intervals are calculated therefrom.

The communication stacks 54 present the other server components 36, 38, 40, 42, 44, 46, 48, 50, 52 with a common generic interface that includes normalization of collected device 10 data into a standard format. The standardization of device 10 data ensures that all other components 36, 38, 40, 42, 44, 46, 48, 52 remain neutral to device type 50.

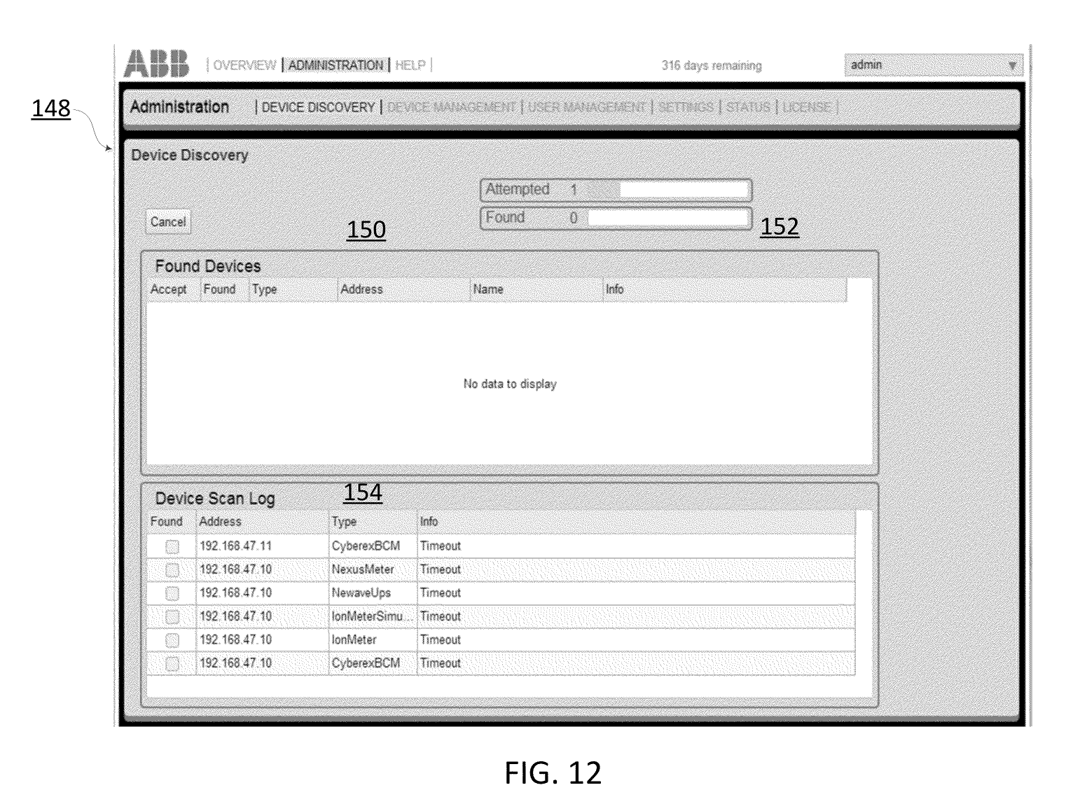

The auto-discovery server 46 uses the communication stacks 54 and device types 50 to identify supported devices 10 to automatically include in the server configuration. The use of automated discovery obviates the need for manual configuration of devices 10 as corresponding representations 51′ in the real-time database 42 in most cases. Alternatively, device representations 51′ that cannot be automatically added to the system 100 are configurable manually as is depicted in FIG. 12 which will be described in more detail below. It should be understood that the device representation 51′ is from the point of view of both the real-time database 42 and the device manager 44.

The auto-discovery server 46 has an agent that locates, for example, Device Type A at a particular IP address in the configuration manager 38 or by using a range of IP addresses in the network or enterprise. The device manager 44 uses the device configuration from the configuration manager 38 to name the device and by the device type 50 to understand how to communicate with the device. For example, the name and the IP address of device type A are used by the device manager 44 to provide a log of data collected from that device 10 to web browsers 30, traditional applications 14 or other systems. By way of non-limiting example, one type of traditional application 14 is a historical database for storing waveforms and associated disturbance data that is older than a predetermined date or time period.

With continued reference to FIG. 2, the real-time database 42 maintains an in-memory repository of real-time device 10 data and events. In this context, real-time means instantaneously and/or nearly instantaneous. The real-time database 42 is updated with device 10 data collected through the communication stacks 54 by the device types 50. The real-time database 42 supports other subsystems 36, 38, 40, 48 that require real-time data and events.

The protocol servers 48 support technology applications through the use of industry standard and proprietary protocols such as OPC UA and Modbus TCP, by way of non-limiting example. The protocol servers 48 access the real-time database 42 in response to requests from external applications such as web browsers, web portals, and traditional applications 14, 30.

A web server 36 and network connected server 40 support modern web- and cloud-based applications. The web server 36 delivers web pages having both static information as well as data extracted from the real-time database 42 and configuration manager 38. As is well known, web socket servers such as network connected server 40 support dynamic updates of real-time data to web pages 30 delivered by the web server 36. The network connected server 40 is also utilized by real-time web applications 30 which do not require a user interface directly from the server.

Referring now to FIG. 2b, the real-time in-memory database 42 is depicted along with a set of actions 53 and notifications 55 that are inputs and outputs, respectively. The in-memory database 42 is an object-oriented database. In the real-time in-memory database 42, the device type 50 is an object that has an array of properties such as configuration, real-time, and disturbance properties 57, 59, 75.

The configuration properties 57 are IP address or other specific information for the brand of power quality meter. The real-time properties 59 are measured using the devices and normalized. An example of a real-time property 59 is voltage being measured at a measurement point in a data center. For example, if a voltage value is measured at 0.01 volts but read from the device as an integer of value 1 the normalization of the voltage value requires division by 100 to obtain a real value. The normalized value is then stored in the in-memory database 42 as a real-time property 59. Another example of normalization is calculation of a standard property that is not directly available from the device. In this case other measurements would be used to compute the measurement.

Real-time and disturbance property 59, 75 values are inputs that can be used to calculate a standard property value n 67. One example is daily power usage for the data center. In this case, the in-memory database 42 accesses a set of hourly values and sums the hourly values to generate a standard property value for the daily power usage. The daily power usage is then transmitted to the power quality server 20.

There are various actions carried out by the device manager 44 and power quality software 60 that update the real-time database 42. For example, the define device type action 53a is carried out by the device manager 44 which polls the system 100 to find devices 10. Upon finding a new device 10, the device manager 44 requests the device 10 to create a representation 51′ of itself in the real-time database 42.

System code is used to scan the workstation, server, or other computing device for a corresponding software component to create the representation 50′ of the particular device 10 using the device type 50. In one embodiment, the software component used to create the representation 50′ is a dynamic-link library. The device manager 44 uses the corresponding dynamic-link library to create the device type 50 and populate the configuration, real-time and standard properties of the device 10. The representation 51′ of the device 10 is then registered in the real-time database 42 by the device manager 44. For example, because the device type Y is used to create representations 51′ of devices B and C, devices B and C are instances of device type Y 50.

During the creation of the device, action 53b, real-time database makes a copy of the device type 50 defining the device 50′ as an instance of the device type 50. For example, device type Y for each of devices B and C, defining devices B and C as instances of device type Y. When a device 51′ is created it is initialized with default values from the corresponding device type 50. In the case of discovered devices some configuration properties are set (for example, the IP address that was discovered). The user may modify other configuration properties such as in the case of manual creation of the device 51, wherein the user sets all configuration properties 57. The real time properties 59 are updated on each scan of the device 51′.

With continued reference to the actions 53 in FIG. 2b, the device manager 44 is enabled to carry out the delete device 53c action which removes the representation of device 51′ from the real-time database 42.

The enable/disable notifications action 53d is a subscription service that allows a client, such as the traditional application 14 or another application, to receive a notification when configuration, real-time or standard property changes in the real-time database 42. The notification includes the new value for the respective property and depending on the application, may include the prior value, the time of the change, and the username, interface, application or other designation of the entity that made the change.

The read values action 53e accesses the real-time database 42 to read configuration, real-time and standard property values 57, 59, 67 from a device 51′. The read values action 53e generally reads data from the real-time database 42 unmodified. However, an operation to translate the data format to match the request of the calling application 14, 30 may be performed. For example, if the calling application 14, 30 requests a text value, the real-time database 42 formats the real value as a string prior to returning the value for the particular configuration, real-time or standard property 57, 59, 67.

The write values action 53f writes the values for the configuration, real-time and standard properties 57, 59, 67 to the real-time database 42. One example of the write values action 53f is that the device type 50 during a scan of a device 51′ by the device manager 44 will use the write values action 53f to update the real-time database 42 with the latest scanned real-time properties 59. The second example is the configuration manager 38 uses a write values action 53f to update changed configuration properties 57 in the real-time database 42.

If new events such as disturbances 73 have been detected since the last read of data from the devices 10, the device manager 44 will instruct the log and waveform collection agent 52 to upload the log or waveform data associated with the occurrence. The device manager 44 has a predetermined read schedule for the devices 10. Based on the schedule, device manager 44 uses the device type 50 to collect the real-time data and events and monitors the events for disturbances 75. The device manager 44 instructs the device 10 to perform readings and also provide an indication of whether the waveform has been collected in the device 10.

With reference now to FIG. 2c, the device disturbance property 75 is shown as defining a set of disturbances 73 (eg. disturbance A, disturbance B . . . disturbance n). The device disturbance waveform parameter value 79 is a text string, real value or set of real values representing characteristics of the particular disturbance 73. Each device disturbance property 75 has parameters 77 including but not limited to the type of disturbance, time of disturbance, trigger time for the scan, and number of samples that are collected along with the waveform parameter values 79. Waveform parameter values 79 include but are not limited to: measurement name which stores the measured value of current or voltage, time of first sample, sample frequency, number of samples, and sample set.

Disturbances 73 are detected by the device manager 44 in response to a device 10 detecting changes in the properties of the power system being measured. Examples of disturbances 73 are voltage sag, swell and transients measured at measurement points such as the power source or main power feed from a utility. When a disturbance is detected, the newly detected disturbance is added at step 71a to the device disturbance property 75. Then, the waveforms 77 characterizing the disturbance 73 are added at step 71c to the device disturbance property 75. Next, through the device type 50 the disturbance is read at step 71d. At step 71e, each waveform that the device 10 recorded for the particular disturbance 73 is read.

Disturbances are also removed at step 71b using the device manager 44 on an as needed basis. Algorithms such as maximum number of retained disturbances or the age of a disturbance are used, but limited to determining when the disturbance will be removed.

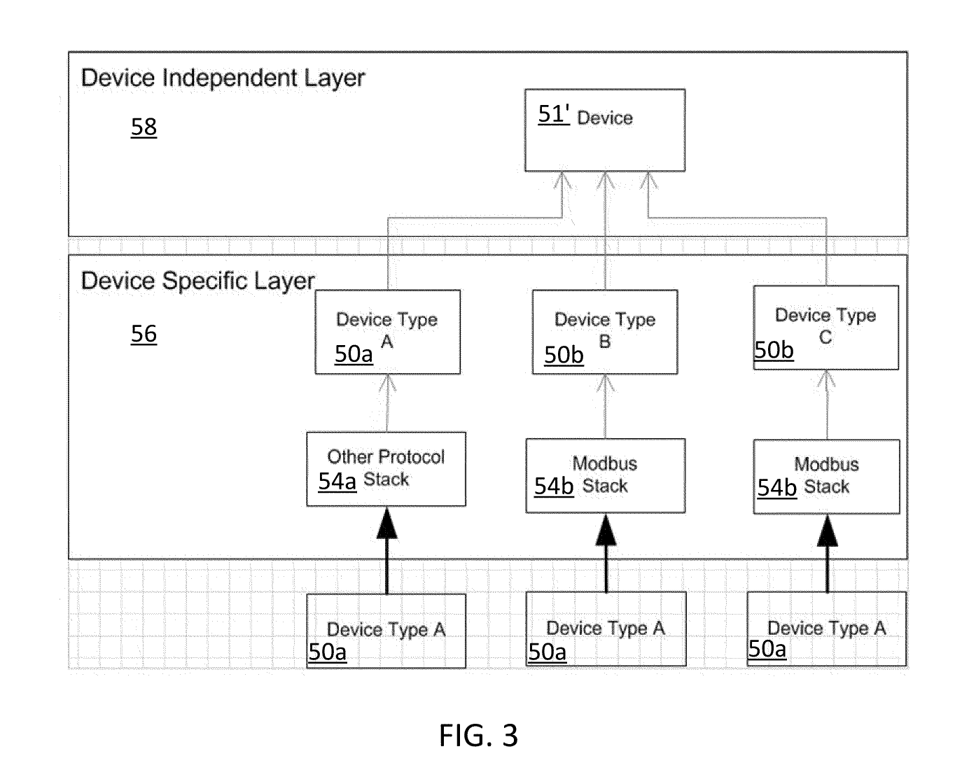

With reference now to FIG. 3, the abstraction performed at the device type 50 level of the computer application 60 of power quality system 100 is shown. Data format conversions are performed at the device type 50 level to achieve an abstract representation of the data stored in the particular device 10. Heterogeneous devices 10 having type A, type B, and Type C device types 50 are part of the device specific layer 56. The abstraction unifies each of the devices 10 and the device 10 data as a general device 51′ in the device independent layer 58 having a standardized data structure.

The device manager 44 communicates to the device type 50 and requests the collection of information at the IP address corresponding to the device 10. The device type 50 uses the communication stack 54 to determine the format for the collection of data from the devices 10. The device type 50 uses the communication stack 54 to issue commands to the device 10 for the extraction and transmission of data in the specified format so that all disparate data collected from the various devices is converted to a common format in the device independent layer 58. Different device types 50b, 50c may utilize the same communication stack 54b.

In one embodiment, the device types 50 represent a mapping from a specific set of device 10 properties to a standardized set of device properties. In that same embodiment, the data is received from the devices 10, parsed, formatted, and stored in a device independent database, such as real-time database 42, having a common data structure for storing all device 10 data. The data may be received in a string from the devices 10 and using the device type 50 parsed and formatted to provide data fields such as meter name, meter type, measurement point, time, date, type of characteristic value, and value of characteristic being measured such as current or voltage. The data is then stored in the real-time database 42.

With reference now to FIG. 4, a graphical user interface of a DCIM computer application 60 depicting an overview 63 of the devices 10 monitoring the electrical system is displayed on a screen of a computer at the location being monitored such as, by way of non-limiting example, a data center. Alternatively, the GUI is displayed on a mobile device such as a smartphone or tablet when the user of the mobile device is within proximity of the monitoring system 100 or an individual device 10. The computer and/or mobile device has a processor and computer readable medium having program instructions stored thereon, which when executed by the processor are operable to receive the power quality data interpreted by the system 100 and present the power quality data to a user for monitoring the system 100 and responding to the information presented.

With continued reference to FIG. 4, the overview tab/screen 63 shows the status of each of the devices 10, in this case, power quality meters, monitoring the electrical system. The real power (kW), real energy (kWh) and power factor as measured or determined from the measurements made by each device 10 are shown. The real power (kW), real energy (kWh) and power factor are key performance indicators (KPIs) corresponding to the device type 50. Depending on the device type 50, different KPIs may be displayed. For example, a UPS has the KPIs real power (kW), power factor, and battery time and a BCM displays the total current measured in each circuit of a PDU.

An indicator 61 corresponds to the measurement for each parameter being measured. The indicator 61 is completed according to the percentage of the maximum value of the range for the measurement. In the present example, the lag of current to voltage is shown as 0.928 and the maximum power factor value is 1 when the current and voltage are in phase. Therefore, the indicator 61 is 92.8% filled or completed in relation to the entire possible length of the bar based on comparing the measured value to the maximum value.

Further, the indicators 61 may be color-coded using different colors for each status to represent normal or acceptable operating values, warning values and values requiring immediate action. Alternatively, the indicators 61 may have different patterns or symbols to represent different alarm statuses that require acknowledgement by a user. It should be understood that all screens containing measured or calculated values may contain indicators 61 even though not explicitly shown. Further, any calculated values are determined using equations known to a person having ordinary skill in the art.

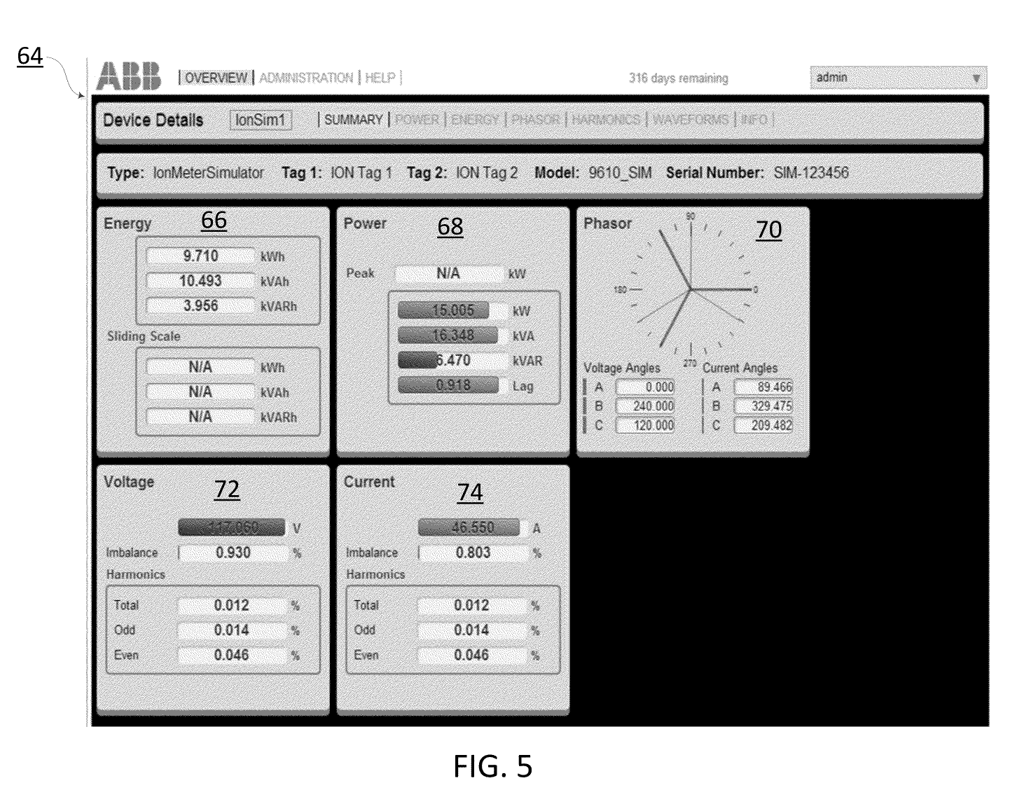

With reference now to FIG. 5, a device display 64 depicting the measurements of a particular device 10 is shown. An energy pane 66 is shown having energy values measured over a predetermined period of time as provided in the settings configuration of the application 60. A power pane 68 shows the peak, complex and reactive power values. A phasor display 70 shows the voltage and current phasors for the three-phase system being measured. The voltage and current panes 72, 74 display voltage and current harmonics and phase imbalance percentages.

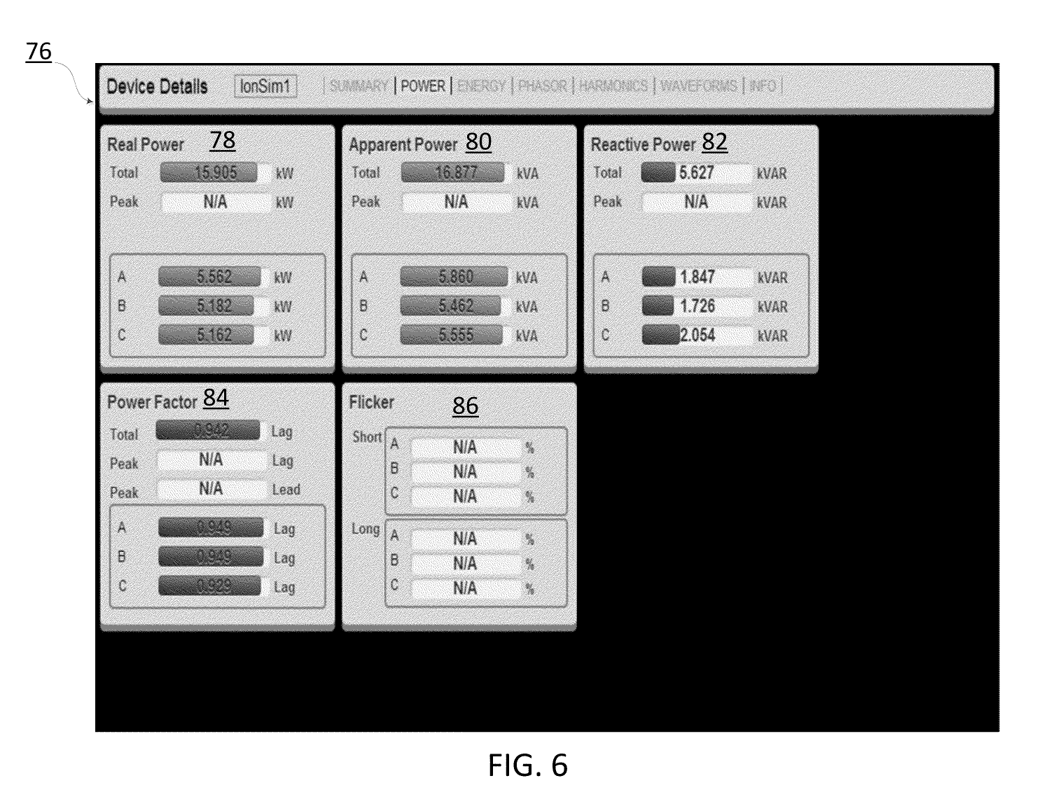

Referring now to FIG. 6, a power tab 76 for the device 10 is shown. Total and Peak values for real, apparent and reactive power 78, 80, 82 are shown along with corresponding values for each phase A, B, and C. A power factor pane 84 is shown with phase lags and leads for the system at the measurement point and each of the phases A, B, and C.

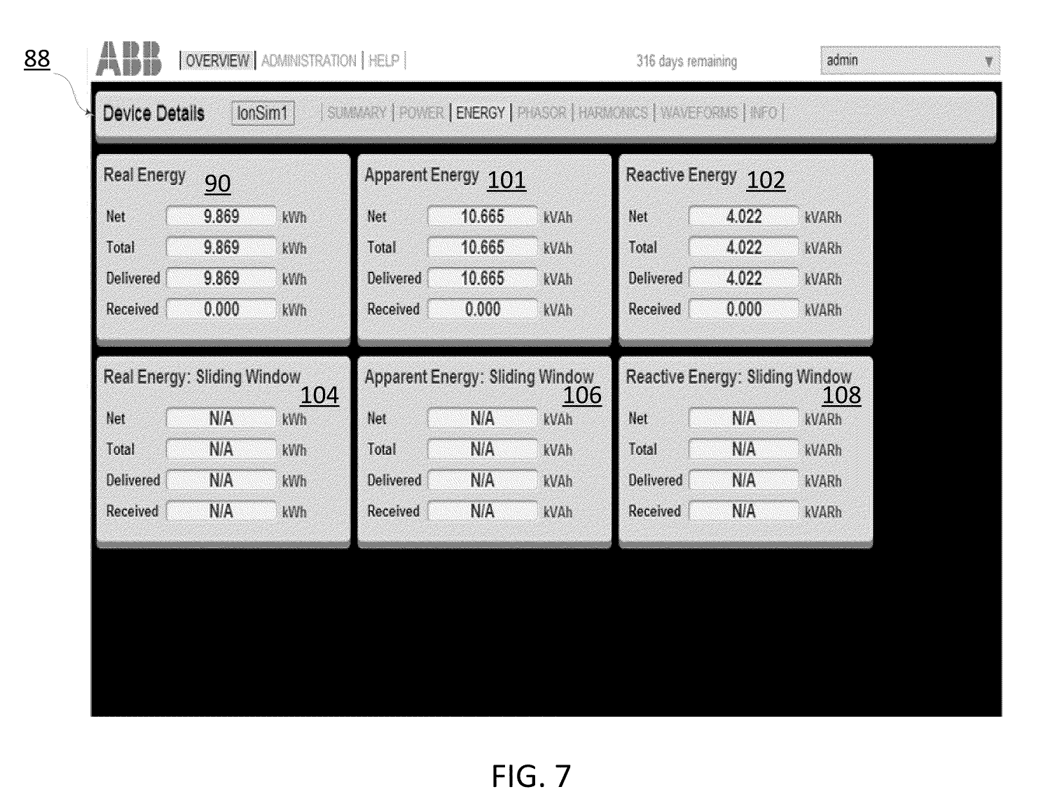

A flicker pane 86 in the power tab 76 shows the percentage of short and long flicker in each of the phases A, B, and C. The flicker pane 86 depicts the flicker perceived by humans in traditional lighting. The flicker is caused by a larger load size in respect to the prospective short circuit current available at the measurement point. The start-up of large motors or other equipment on the electrical system may result in the human eye-brain perception of flicker. With reference now to FIG. 7, an energy tab 88 of the application 60 is shown. Panes 90, 101, 102 depict real, apparent, and reactive energy values as net, total, delivered and received, respectively. Panes 104, 106, 108 display real, apparent, and reactive energy values for a predetermined time frame such as minutes, a month, or any desired time frame.

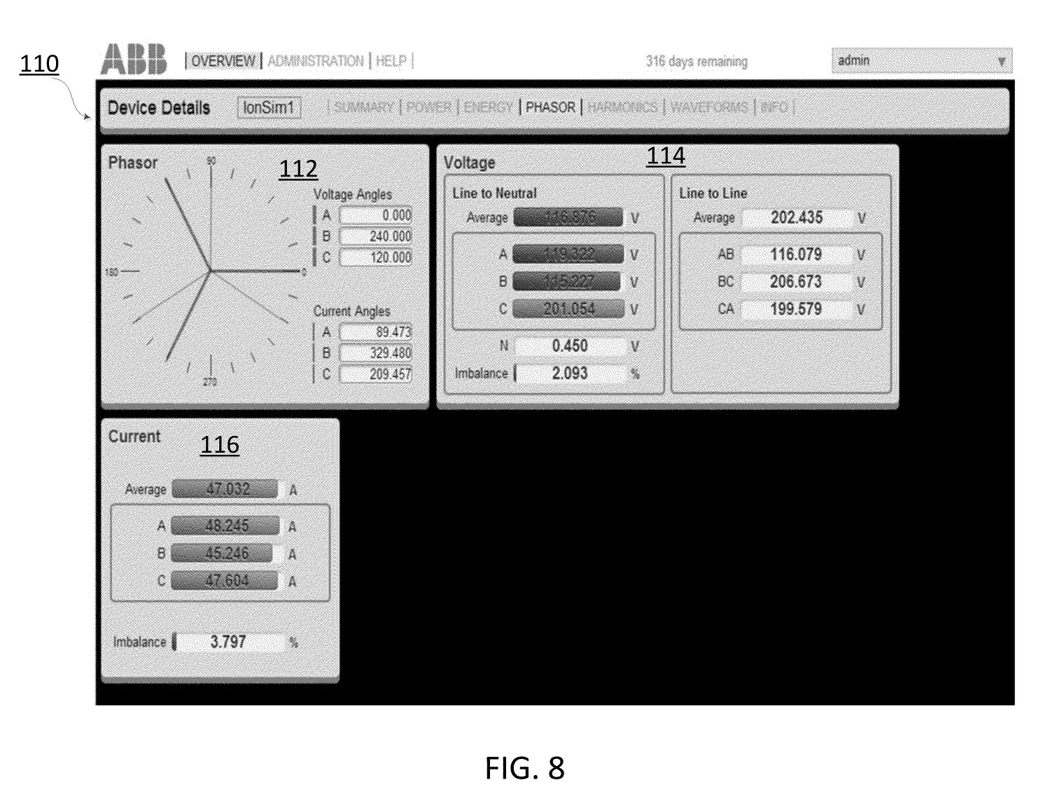

Referring now to FIG. 8, a phasor tab 110 of the application 60 is shown. The current and voltage phasors are depicted in the phasor pane 112. Further, a voltage pane 114 shows line to neutral voltage values for each phase to neutral and the average voltage value for line to neutral. An imbalance percentage represents the difference in current values between the phases. For example, if one phase has a high current while another phase has a low current, a high imbalance percentage results. Line-to-line average voltage and line-to-line voltage values are shown for A to B, B to C, and C to A conductors. A current pane 116 depicts current values for each of the phases as well as the average current for the system or measurement points.

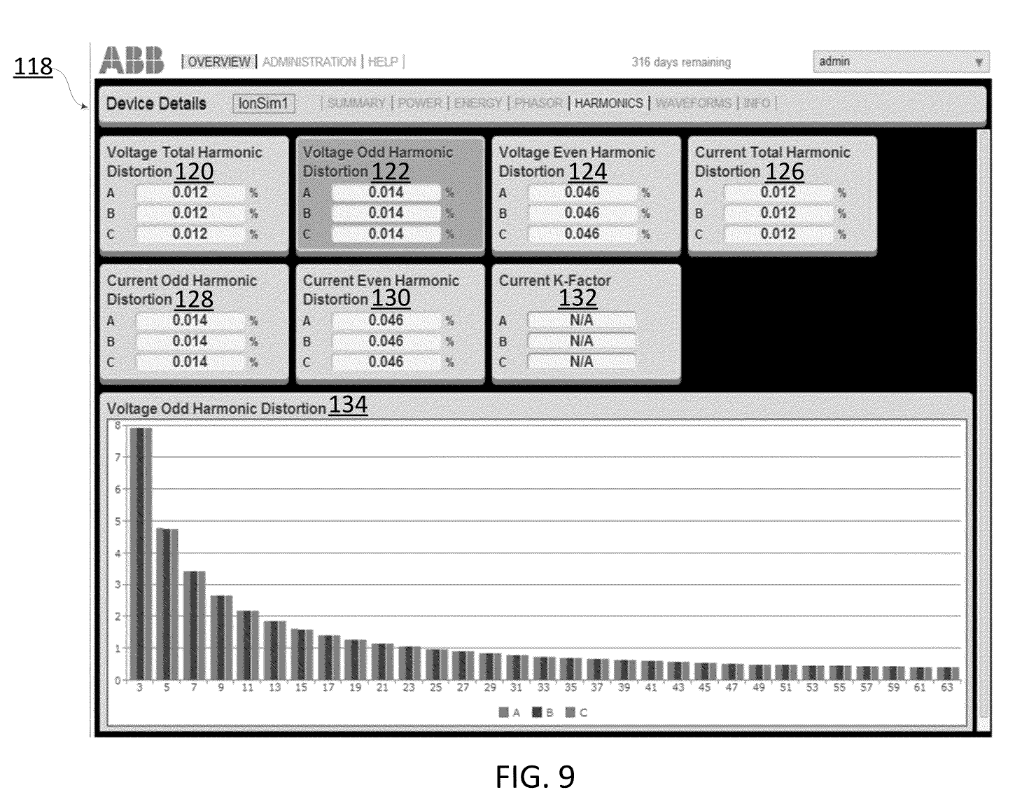

With reference now to FIG. 9, a harmonics tab 118 of the application 60 is shown. The voltage and current even, odd and total harmonic distortion for each phase is shown as a percentage. A bar chart 134 showing a time series for voltage odd harmonic distortion 122 is depicted and similar charts are available for each type of harmonic distortion for which values are available from the respective devices 10. For example, the bar chart 134 shows the odd harmonic values of the 3^{rd} order, the 5^{th} order and so on. The even harmonic distortion panes 124, 130 show the even harmonic values of the 2^{nd} order, 4^{th} order, 6^{th} order and so on. The total harmonic distortion panes 120, 126, if selected for the generation of a bar chart 134, would display all orders of harmonic distortion values available.

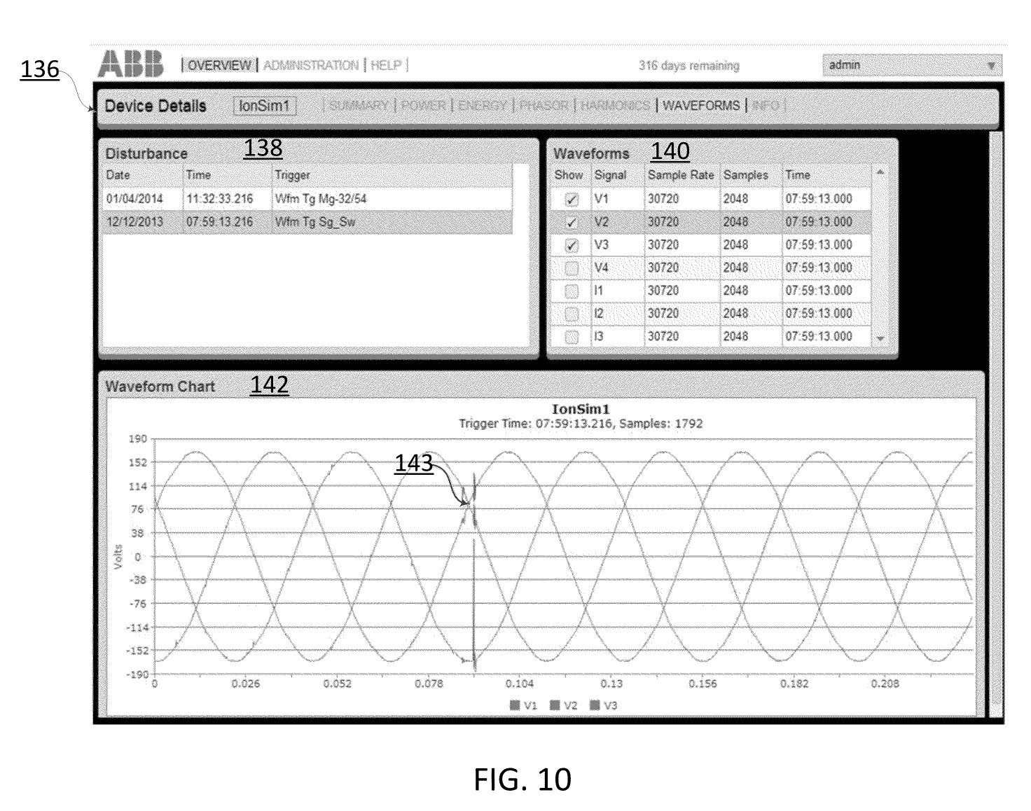

With reference now to FIG. 10, a waveform tab 136 of the DCIM application 60 is depicted. A particular disturbance 143, such as a sag or swell, is measured by a device 10 at the time and date shown in the disturbance pane 138. The DCIM application determines the data and time of the disturbance 143 from the device 10 data. Voltage and current values for a time interval prior to, during and after the disturbance or transient are measured or isolated from a larger set of data for each of the phases in the system by the DCIM application 60. The particular parameters and phases of interest are selectable in the waveform pane 140 to generate a waveform plot 142 from the selected values. In the present example depicted in FIG. 10, voltage values for each phase V1, V2, V3 for 2048 samples at a sample rate of 30720 samples per second are taken beginning at the trigger time of 7:59:13.

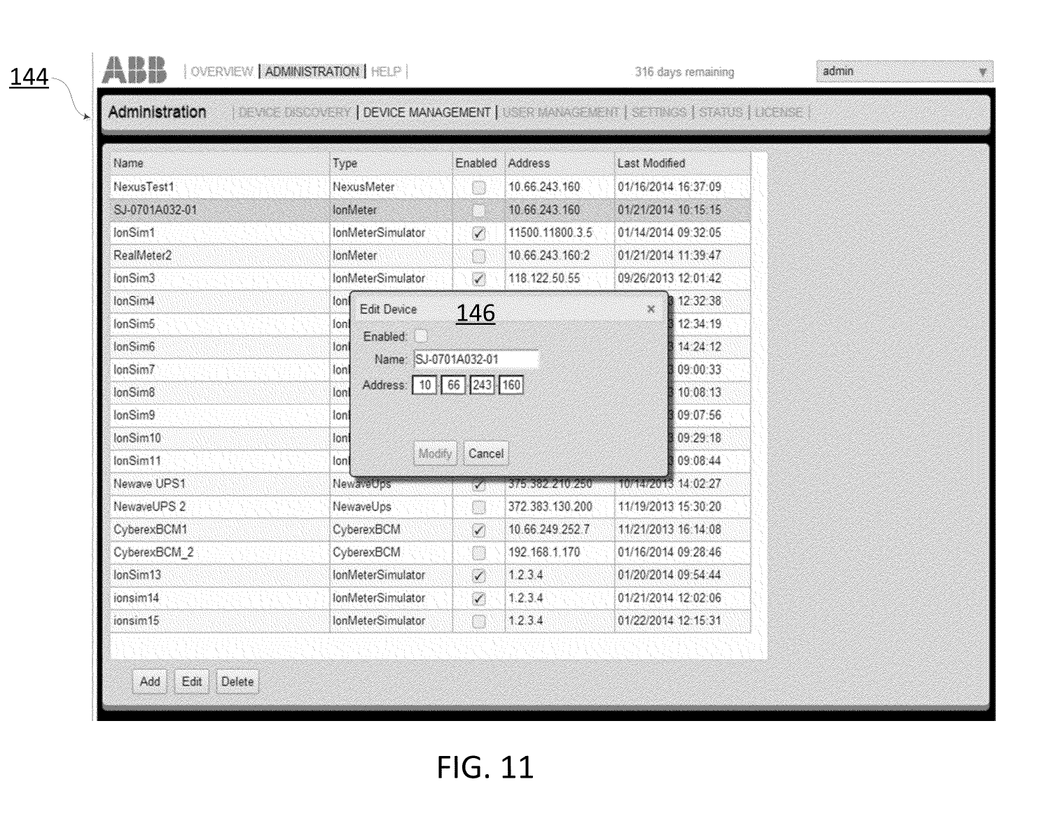

With reference now to FIGS. 11 and 12, a device management tab 144 of the DCIM application 60 is shown. The device 10 configuration is carried out in the device management tab 144 wherein the device 10 address and name are input manually in a pop-up box 146 or discovered automatically by the device discovery agent 46 shown in FIG. 12. The device discovery agent 46 uses the communication stacks 54 and device type 50 to identify the devices 10 that are available at particular addresses or a range of addresses, for automatic addition to the configuration.

FIG. 12 shows a discovery scan in progress. At this point in the discovery scan, six devices have been attempted and none have yet to be found. In the event a device 10 is found, the device 10 appears in the found devices section and the user is presented with the option to accept the found device(s) 10 in the configuration or to skip the found devices 10.

A method for power quality monitoring through communication and standardization of power quality data obtained from heterogeneous devices has the following steps:

associating each said device with a device type;

creating a representation of each said device in a real-time database using said device type;

routing a device request associated with each said device to a communication stack;

retrieving power quality data from each said device through said communication stack and device type;

converting said power quality data from device dependent data to device independent data; and

updating said real-time database with device independent data from said plurality of devices; and wherein

the computer program product has computer-readable program instructions on a non-transitory computer readable medium, said computer-readable program instructions that when executed by a processor, carry out the steps of unifying said device data into a power quality display representing the plurality of devices being monitored by said power quality system.

Further, the device independent data is transmitted from said real-time database to a web application, DCIM system, or another application.

While the present application illustrates various embodiments, and while these embodiments have been described in some detail, it is not the intention of the applicant to restrict or in any way limit the scope of the appended claims to such detail. Additional advantages and modifications will readily appear to those skilled in the art. Therefore, the invention, in its broader aspects, is not limited to the specific details, the representative embodiments, and illustrative examples shown and described. Accordingly, departures may be made from such details without departing from the spirit or scope of the applicant's general inventive concept.

What is claimed is:

1. A method for power quality monitoring, comprising computer-readable program instructions stored on a non-transitory computer readable medium that when executed by a processor, carry out the steps of unifying measurements from a plurality of devices into standardized power quality data representing said plurality of devices, comprising:
a. associating each said device with a device type;
b. creating a representation of each said device in a real-time database using said device type;
c. routing a device request associated with each said device to a communication stack;
d. retrieving power quality data from each said device through said communication stack and device type;
e. converting said power quality data from device dependent data to device independent data; and
f. updating said real-time database with device independent data from said plurality of devices.

2. The method of claim 1, further comprising:
g. transmitting said device independent data from said real-time database to at least one of a web application, DCIM system, or another application for presenting a power quality display representing said plurality of devices.

3. The method of claim 1 wherein the devices are discovered by a device manager prior to association with said device type.

4. A system for unifying power quality measurements from a plurality of devices in a real-time database of standardized power quality data, comprising:
a power quality server in communication with said plurality of devices and at least one other application requesting said power quality data from said plurality of device, said power quality server comprising:
a device manager for managing the collection of waveforms by said plurality of devices; and
a real-time in-memory database for storage of properties describing disturbances in said waveforms collected by said plurality of devices.

5. The system of claim 4 wherein the real-time database is in bi-directional communication with at least one web application to provide real-time analysis of said standardized power quality data.

6. The system of claim 4, wherein the disturbances are at least one of voltage sag, voltage swell, and transients.

7. The system of claim 4, wherein the disturbance is transmitted to a web application and provides an alarm to a user.

8. A computer program product for unifying power quality measurements from a plurality of disparate devices comprising computer-readable program instructions stored on a non-transitory computer readable medium that when executed by a processor, carries out the following steps:
a. associating each said device with a device type;
b. creating a representation of each said device in a real-time database using said device type;
c. routing a device request associated with each said device to a communication stack;
d. retrieving power quality data from each said device through said communication stack and device type;
e. converting said power quality data from device dependent data to device independent data; and
f. updating said real-time database with device independent data from said plurality of devices.

9. The method of claim 8, further comprising: g. transmitting said device independent data from said real-time database to at least one of a web application, DCIM system, or another application for presenting a power quality display representing said plurality of devices.
